(19) United States
(12) Patent Application Publication
(10) Pub. No.: US 2024/0002724 A1
(43) Pub. Date: Jan. 4, 2024

(54) COPOLYMER FOR QUANTUM DOT LIGAND, AND QUANTUM DOT COMPLEX, QUANTUM DOT COMPOSITION, AND LIGHT-EMITTING DEVICE INCLUDING THE SAME

(71) Applicants: Samsung Display Co., Ltd., Yongin-si (KR); Hannam University Institute for Industry- Academia Cooperation, Daejeon (KR)

(72) Inventors: Yunhyuk Ko, Yongin-si (KR); Changhee Lee, Yongin-si (KR); Taedong Kim, Daejeon (KR); Prem Prabhakaran, Daejeon (KR); Kanghyeok Lee, Daejeon (KR)

(21) Appl. No.: 18/320,086

(22) Filed: May 18, 2023

(30) Foreign Application Priority Data
Jul. 4, 2022 (KR) 10-2022-0082140

(51) Int. Cl. C09K 11/88; H01L 33/06; H01L 33/26; C09K 11/06

(52) U.S. Cl. CPC C09K 11/883; H01L 33/06; H01L 33/26; C09K 11/06; B82Y 20/00

(57) ABSTRACT

A quantum dot ligand, a quantum dot complex including the same, a quantum dot composition including the quantum dot complex, and a light-emitting device including the quantum dot complex are provided. The quantum dot ligand is a polymer including: a first unit having a functional group having a charge transport function; and a second unit having at least one crosslinkable functional group and at least one functional group capable of binding to a quantum dot.

### CROSS-REFERENCE TO RELATED APPLICATION

This application claims priority to and the benefit of Korean Patent Application No. 10-2022-0082140, filed on Jul. 4, 2022, in the Korean Intellectual Property Office, the disclosure of which is incorporated herein by reference in its entirety.

### BACKGROUND

### 1. Field

One or more embodiments relate to a copolymer for a quantum dot ligand, and a quantum dot complex, a quantum dot composition, and a light-emitting device, each including the same.

### 2. Description of the Related Art

Quantum dots made of a semiconductor compound have a quantum confinement effect and can easily control their semiconductor properties through controlling the size of the quantum dots. For this reason, quantum dots are widely utilized in fields such as displays, solar cells, lighting, bioimaging, and/or biosensing.

Colloidal quantum dots can be stabilized by organic ligands to maintain dispersion stability in solvents. The organic ligands of quantum dots can also passivate traps on the surface of quantum dots so that photoluminescence quantum yields are improved, and quantum dots are stabilized against aggregation and degradation.

In the manufacture of a quantum dot device, it is desirable or important to prevent or reduce aggregation of quantum dots in a quantum dot composition and to secure dispersion in a solvent. For this purpose, quantum dot ligands with long alkyl groups, such as oleic acid and/or oleylamine, are utilized. However, the insulating properties of alkyl groups may interfere with charge injection, thereby impairing the performance of a light-emitting device.

### SUMMARY

Aspects according to one or more embodiments are directed toward: a copolymer for quantum dot ligands that prevent or reduce aggregation of quantum dots, and have good or suitable charge mobility while ensuring dispersion in organic solvents; quantum dot complexes including the same; quantum dot compositions including the quantum dot complexes; and light-emitting devices including the same.

Additional aspects will be set forth in part in the description which follows and, in part, will be apparent from the description, or may be learned by practice of the presented embodiments of the disclosure.

According to one or more embodiments, a copolymer for quantum dot ligands include:

a first unit including a functional group having a charge transport function; and

a second unit including at least one crosslinkable functional group and at least one functional group capable of bonding to a quantum dot.

The functional group having the charge transport function may include a carbazolyl group, a pyrenyl group, a fluorenyl group, an amino group, a pyridyl group, a pyrimidyl group, a triazine group, a phenanthroline group, a benzimidazole group, an oxadiazole group, a triazole group, an adamantane group, a benzothiadizole group, a diketopyrrolopyrrole group, a truxene group, or any combination thereof.

The functional group having the charge transport function may include at least one functional group represented by Formula A-1 to Formula A-15:

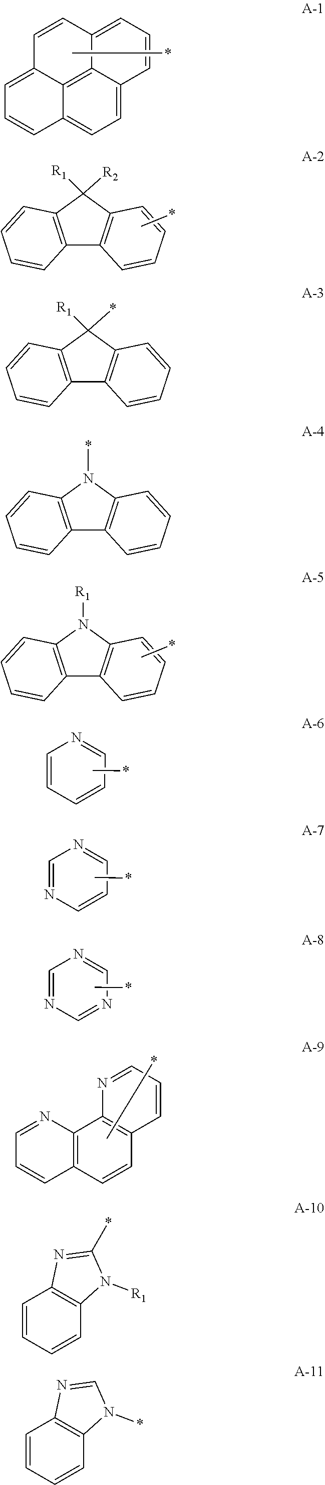

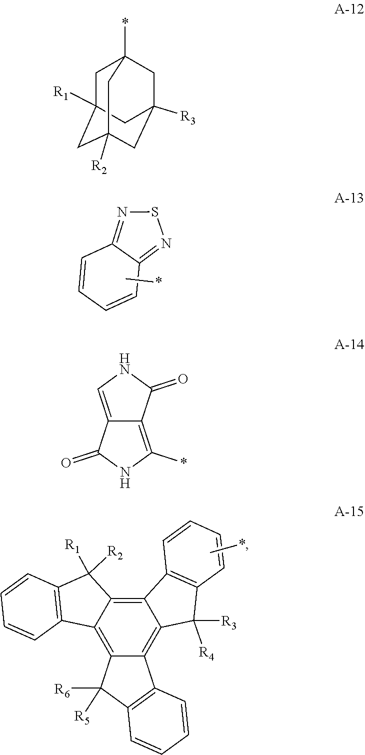

wherein, in Formulae A-1 to A-15,

R₁ to R₆ may each independently be hydrogen, deuterium, —F, —Cl, —Br, —I, a hydroxyl group, a cyano group, a carboxyl group, a C₁-C₂₀ alkyl group, —Si(Q₁)(Q₂)(Q₃), or —N(Q₁)(Q₂),

Q₁ to Q₃ may each independently be hydrogen, a C₁-C₂₀ alkyl group, a phenyl group, a biphenyl group, a terphenyl group, a naphthyl group, or a pyridyl group, and

* is a site connected to the copolymer.

The crosslinkable functional group may include an amide group (—CONH-), a urea group (—NHCONH-), or a urethane group (—NHCOO-).

The functional group capable of bonding to the quantum dot may include a thiol group, an amino group, an amine group, a carboxyl group, a halogen group, an amide group, a sulfonic acid group, or a phosphoric acid group.

The functional group capable of bonding to the quantum dot may be a bidentate group or a tridentate group. That is, the functional group capable of bonding to the quantum dot may have two or three bonding sites for the quantum dot.

The second unit may further include a first link portion positioned between the crosslinkable functional group and the functional group capable of bonding to the quantum dot, and when the crosslinkable functional group includes two or more crosslinkable functional groups, the second unit may further include a second link portion positioned between the two or more crosslinkable functional groups.

The quantum dot ligand may include a moiety represented by Formula 2:

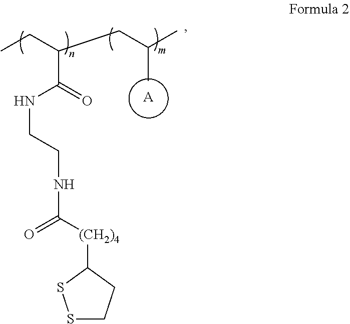

wherein, in Formula 2,

n is an integer selected from 1 to 8, and m is an integer selected from 10 to 15, and

A may include a functional group represented by one of Formulae A-1 to A-11.

A molar ratio of the first unit to the second unit may be 5:1 to 20:1.

A number average molecular weight (Mn) of the copolymer may be 2,000 to 50,000.

According to one or more embodiments, a quantum dot complex includes a quantum dot, and a quantum dot ligand bonded to the quantum dot, wherein the quantum dot ligand includes: a first unit including a functional group having a charge transport function; and a second unit including a cross-linked portion and a quantum dot-bonded portion bonded to the quantum dot.

The functional group having the charge transport function may include a carbazolyl group, a pyrenyl group, a fluorenyl group, an amino group, a pyridyl group, a pyrimidyl group, a triazine group, a phenanthroline group, a benzimidazole group, an oxadiazole group, a triazole group, or a derivative thereof or any combination thereof.

The cross-linked portion may be derived from hydrogen bonding of an amide group (—CONH-), a urea group (—NHCONH-), or a urethane group (—NHCOO-).

The quantum dot-bonded portion bonded to the quantum dot may be derived from bonding of a thiol group, an amino group, an amine group, a carboxyl group, a halogen group, an amide group, a sulfonic acid group, or a phosphoric acid group, to a surface of the quantum dot.

The second unit may further include a first link portion positioned between the cross-linked portion and the quantum dot-bonded portion, and, when the cross-linked portion includes two or more cross-linked portions, a second link portion positioned between the two or more cross-linked portions.

The quantum dot may have a core-shell structure including a core including a first semiconductor, and a shell around the core and including a second semiconductor.

The first semiconductor and the second semiconductor may each independently include ZnS, ZnSe, ZnTe, ZnO, MgSe, MgS, ZnSeS, ZnSeTe, ZnSTe, MgZnSe, MgZnS, CdZnSeS;

GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP;

TiO, GaO, GaS, GaSe, Ga₂Se₃, GaTe, InS, InSe, In₂S₃, In₂Se₃, InTe;

InGaS₃, InGaSe₃;

AgInS, AgInS₂, CuInS, CuInS₂, CuGaO₂, AgGaO₂, AgAlO₂, AgInZnS;

SrSe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe;

Si, Ge, SiC, SiGe, or any combination thereof.

In an embodiment, the first semiconductor may include InP, InZnP, InGaP, CdSe, CdS, CdTe, ZnS, ZnSe, ZnTe, CdSeTe, CdZnS, CdSeS, PbSe, PbS, PbTe, AgInZnS, HgS, HgSe, HgTe, GaN, GaP, GaAs, InGaN, InAs, ZnO, or any combination thereof, and

the second semiconductor may include ZnS, ZnSe, ZnTe, ZnO, CdS, CdSe, CdTe, CdO, InP, InS, GaP, GaN, GaO, InZnP, InGaP, InGaN, InZnSCdSe, PbS, TiO, SrSe, HgSe, or any combination thereof.

According to one or more embodiments, a quantum dot composition includes the quantum dot complex and a solvent.

According to one or more embodiments, a light-emitting device includes a

first electrode, a second electrode facing the first electrode, and a functional layer between the first electrode and the second electrode, wherein the functional layer includes the quantum dot complex.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a diagram conceptually illustrating a copolymer ligand linked by cross-linking;

FIG. 2 is a diagram conceptually illustrating a structure of a quantum dot complex according to an embodiment;

FIG. 3 is a diagram schematically illustrating a structure of a light-emitting device according to an embodiment;

FIG. 4 is a Fourier-transform infrared spectroscopy (FT-IR) spectrum of quantum dot complexes of Examples 1-1 and 1-2 and Comparative Example 1-1;

FIG. 5 is a photoluminescence spectra of the quantum dot complexes of Examples 1-1 and 1-2 and Comparative Example 1-1; and

FIG. 6 is a graph of current efficiency versus luminance of quantum dot light-emitting devices of Example 3-2 and Comparative Example 3-1.

### DETAILED DESCRIPTION

The disclosure may be subjected to one or more suitable modification and may also have one or more suitable embodiments, and specific embodiments are illustrated in the drawings and are described in the detailed description. The effects and characteristics of the disclosure, and a method of accomplishing the same will be apparent when referring to embodiments described with reference to the drawings. The disclosure may, however, be embodied in many different forms and should not be construed as limited to the embodiments set forth herein.

Hereinafter, embodiments of the disclosure will be described in more detail with reference to the accompanying drawings. The same or corresponding components will be denoted by the same reference numerals, and thus redundant description thereof will not be provided.

It will be understood that although the terms “first,” “second,” etc. may be used herein to describe various components, these components should not be limited by these terms. These terms are only used to distinguish one component from another.

An expression used in the singular encompasses the expression of the plural, unless it has a clearly different meaning in the context.

It will be further understood that the terms “comprises” and/or “comprising” as used herein specify the presence of stated features or elements, but do not preclude the presence or addition of one or more other features or elements.

In the following embodiments, when various components such as layers, films, regions, plates, etc. are said to be “on” another component, this refers to not only cases when they are “on” another component, but also includes cases in which other components are interposed therebetween. Sizes of elements in the drawings may be exaggerated for convenience of explanation. In other words, because sizes and thicknesses of components in the drawings are arbitrarily illustrated for convenience of explanation, the following embodiments are not limited thereto.

Hereinafter, a quantum dot ligand, and a quantum dot complex, a quantum dot composition, and a light-emitting device, including the same according to the disclosure will be described in more detail.

### Quantum Dot Ligand

According to one embodiment, a quantum dot ligand that is a copolymer ligand is provided.

A quantum dot ligand according to an embodiment is a copolymer including a first unit and a second unit. The first unit includes a functional group having a charge transport function, and the second unit includes a crosslinkable functional group and a functional group capable of bonding to (e.g., one or more) quantum dots.

The functional group having a charge transport function in the first unit may include a functional group having a hole transport function, an electron transport function, or both (e.g., simultaneously) the hole transport function and the electron transport function.

The functional group having the charge transport function may include, for example, a carbazolyl group, a pyrenyl group, a fluorenyl group, a pyridyl group, a pyrimidyl group, a triazine group, a phenanthroline group, a benzimidazole group, an oxadiazole group, a triazole group, an adamantane group, a benzothiadizole group, a diketopyrrolopyrrole group, a truxene group, or a derivative thereof.

The functional group having the charge transport function may include, for example, one of the functional groups represented by Formulae A-1 to A-15:

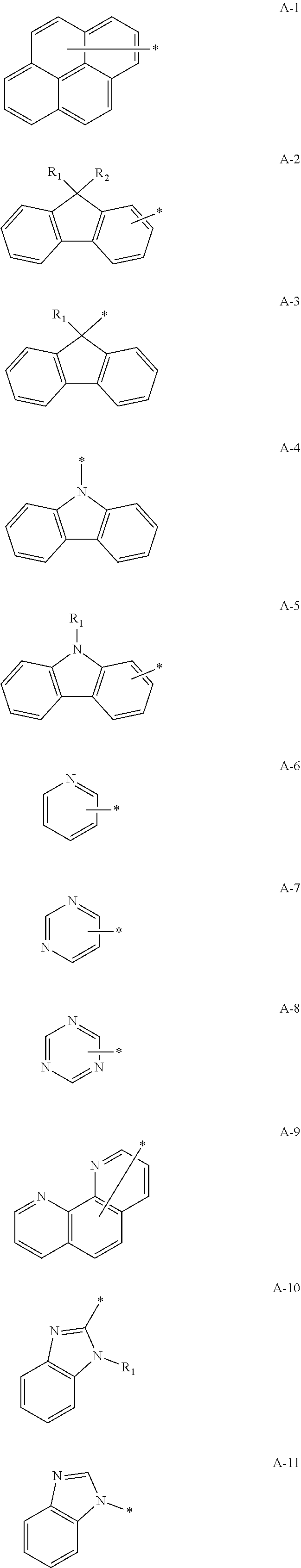

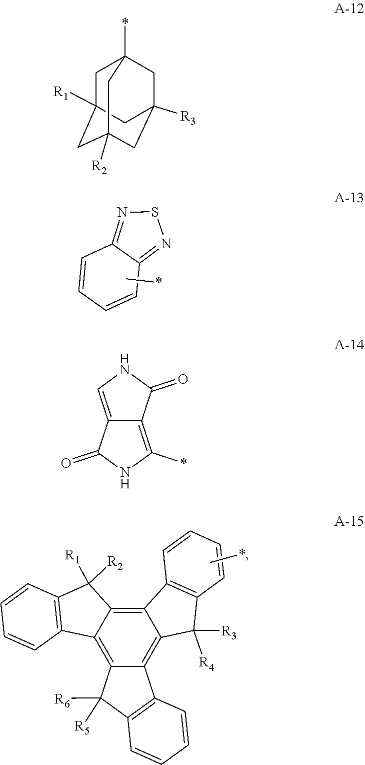

wherein, in Formulae A-1 to A-15,

R₁ to R₆ may each independently be hydrogen, deuterium, —F, —Cl, —Br, —I, a hydroxyl group, a cyano group, a carboxyl group, a C₁-C₂₀ alkyl group, —Si(Q₁)(Q₂)(Q₃), or —N(Q₁)(Q₂),

Q₁ to Q₃ may each independently be hydrogen, a C₁-C₂₀ alkyl group, a phenyl group, a biphenyl group, a terphenyl group, a naphthyl group, or a pyridyl group, and

* is a moiety (e.g., site) connected to the quantum dot ligand.

The functional group having a charge transport function may include, in addition to the functional groups represented by Formulae A-1 to A-15, any suitable hole transporting group, any suitable electron transporting group, or any suitable functional group having both (e.g., simultaneously) a hole transport function and an electron transport function. In some embodiments, the functional group represented by

Formulae A-1 to A-15 may further include a substituent. The substituent may include, for example, deuterium, a halogen atom, a hydroxyl group, a cyano group, and/or a C₁-C₂₀ alkyl group.

The crosslinkable functional group in the second unit may include a functional group capable of hydrogen bonding. The crosslinkable functional group may include, for example, an amide group (—CONH-), a urea group (—NHCONH-), or a urethane group (—NHCOO-). The amide group, the urea group, the urethane group, or an ester group, present at different positions in the quantum dot ligand, may be cross-linked through mutual hydrogen bonding (C═O . . . HN). The crosslinkable functional group in the second unit may exist as one or more crosslinkable functional groups. For example, the second unit may include 1, 2, or 3 crosslinkable functional groups.

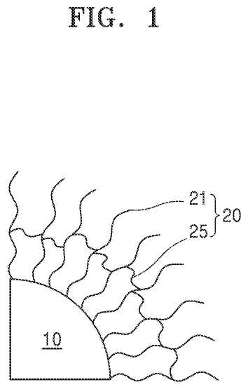

FIG. 1 is a diagram conceptually illustrating a copolymer ligand 20 linked by cross-linking. Referring to FIG. 1, units 21 of the copolymer ligand 20 are cross-linked together by the cross-linked portions 25 to evenly passivate the surface of a quantum dot 10 to take a stable shape. Because the copolymer ligand 20 is evenly distributed on the surface of the quantum dot 10, the quantum dot 10 may be uniformly distributed in a colloidal state without being aggregated in a solvent, and may exhibit substantially uniform charge transport characteristics.

The functional group capable of bonding to quantum dots in the second unit may include a thiol group, an amino group, an amine group, a carboxyl group, a halogen group, an amide group, a sulfonic acid group, a phosphoric acid group, and/or the like. The second unit may include one or more functional groups capable of bonding to quantum dots. For example, a bidentate or tridentate thiol group may be included as the functional group capable of bonding to quantum dots. For example, the bidentate thiol group may be a 1,2-dithiolane group or a group derived therefrom.

The second unit may further include a link portion between the functional groups. For example, a first link portion may be included between the crosslinkable functional group and the functional group capable of bonding to quantum dots. In some embodiments, when the crosslinkable functional group includes a plurality of crosslinkable functional groups, a second link portion may be further included between the crosslinkable functional groups.

The link portion may include a C₁-C₁₀ alkylene group. The C₁-C₁₀ alkylene group may include, for example, a methylene group, an ethylene group, an n-propylene group, an n-butylene group, an n-pentylene group, an n-hexylene group, and/or the like, but is not limited thereto. When there are a plurality of link portions, the plurality of link portions may be the same or different from each other.

By adjusting the length of the link portion, the length of the quantum dot ligand may be adjusted. The length of the quantum dot ligand may affect the distance between the quantum dots, thereby affecting the dispersion of the quantum dots.

According to one embodiment, the second unit of the quantum dot ligand may be a unit represented by Formula 1.

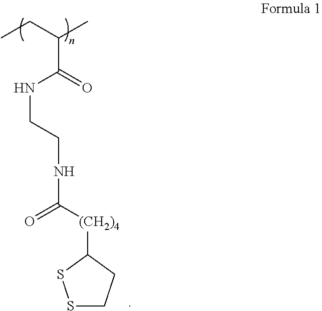

In Formula 1, n may be an integer of 1 to 5.

According to an embodiment, the quantum dot ligand may be a copolymer represented by Formula 2.

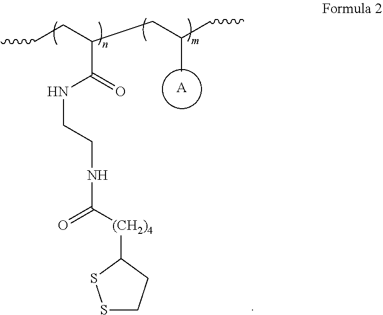

In Formula 2,

n may be an integer from 1 to 5, m may be an integer from 10 to 15,

A may be a suitable charge-transporting functional group. A may be, for example, a functional group represented by any one of Formulae A-1 to A-13 described above.

[symbol] in Formula 2 is a terminal portion of the main chain of the copolymer to which the first unit and the second unit are connected, and may have a suitable structure.

According to one embodiment, the quantum dot ligand (e.g., the copolymer for quantum dot ligands) may be represented by Formula 3.

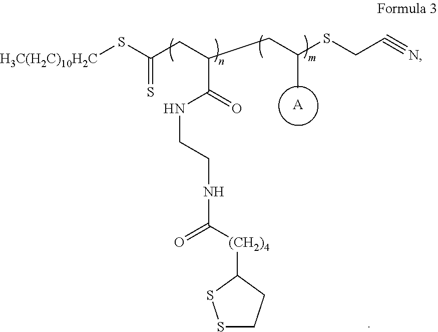

wherein, in Formula 3,

n and A refer to n and A in Formula 2, respectively.

The molar ratio of the first unit to the second unit may be from 2:1 to 15:1, for example, from 3:1 to 10:1, or from 5:1 to 8:1. When the molar ratio of the first unit to the second unit is within these ranges, the quantum dots having the copolymer ligand may have good or suitable solvent dispersion properties and electron transport properties.

The number average molecular weight (Mn) of the copolymer ligand may be about 1,000 to about 50,000, about 5,000 to about 20,000, or about 5,000 to about 10,000. For example, the number average molecular weight (Mn) of the copolymer ligand may be about 1,700 to about 12,000. The weight average molecular weight (Mw) of the copolymer ligand may be about 1,000 to about 50,000, about 5,000 to about 20,000, or about 5,000 to about 10,000. For example, the weight average molecular weight (Mn) of the copolymer ligand may be about 1,700 to about 12,000. The ratio of the number average molecular weight (Mn) to the weight average molecular weight (Mw) of the copolymer ligand may be 1.0 to 1.3. When the molecular weight of the copolymer ligand is within these ranges, the charge transport function of the copolymer ligand is good or suitable, and adhesion of the copolymer ligand to the quantum dots may be suitably maintained (e.g., maintained well).

### Quantum Dot Complex

According to another aspect, a quantum dot complex having the quantum dot ligand is provided.

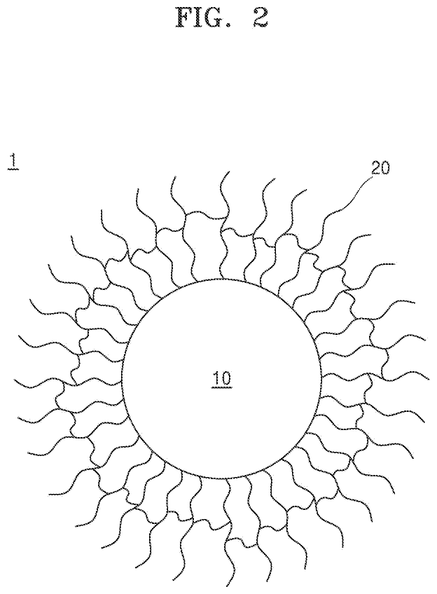

FIG. 2 is a diagram conceptually illustrating the structure of a quantum dot complex 1 according to an embodiment.

Referring to FIG. 2, the quantum dot complex 1 includes at least one quantum dot 10 and a copolymer ligand 20 disposed on the surface of the quantum dot 10.

According to one embodiment, the quantum dot 10 may have a single structure or a core-shell structure, and the shell may include a single layer or multiple layers. The core may include a first semiconductor, and the shell may include a second semiconductor. Each of the first semiconductor and the second semiconductor may include one or more semiconductor materials. For example, when the shell includes two layers, the first layer may include a 2^{nd}-1^{st} semiconductor, and the second layer may include a 2^{nd}-2^{nd} semiconductor. In some embodiments, for example, when the shell includes three layers, the first layer may include a 2^{nd}-1^{st} semiconductor (e.g., a second semiconductor), the second layer may include a 2^{nd}-2^{nd} semiconductor (e.g., a third semiconductor), and the third layer may include a 2^{nd}-3^{rd} semiconductor (e.g., a fourth semiconductor). The core and each of the shells may be made of different materials. When the shell is multiple layers, some layers may be made of the same material. In one embodiment, one shell may include a plurality of semiconductor materials, and the semiconductor materials may have a concentration gradient within the shell. In one embodiment, a plurality of shells may include a plurality of semiconductor materials, and the semiconductor materials may have a concentration gradient within the shell.

According to an embodiment, the semiconductor materials may include a Group II-VI semiconductor, a Group III-V semiconductor, a Group IV-VI semiconductor, or a Group IV semiconductor, or any combination thereof. The semiconductor materials may be a one-element semiconductor, a two-element semiconductor, a three-element semiconductor, or a four-element semiconductor, or any combination thereof. Each element included in the multi-element semiconductor may be present in a substantially uniform or non-uniform concentration in the core or the shell. For example, the constituent elements of the semiconductor material may have a concentration gradient within the core or the shell.

According to an embodiment, the first semiconductor material to the fourth semiconductor material may each independently include, for example, ZnS, ZnSe, ZnTe, ZnO, MgSe, MgS, ZnSeS, ZnSeTe, ZnSTe, MgZnSe, MgZnS, CdZnSeS;

GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, InAlZnP;

TiO, GaO, GaS, GaSe, Ga₂Se₃, GaTe, InS, InSe, In₂S₃, In₂Se₃, InTe; InGaS₃, InGaSe₃;

AgInS, AgInS₂, CuInS, CuInS₂, CuGaO₂, AgGaO₂, AgAlO₂, AgInZnS; SrSe, SnS, SnSe, SnTe, PbS, PbSe, PbTe, SnSeS, SnSeTe, SnSTe,

PbSeS, PbSeTe, PbSTe, SnPbS, SnPbSe, SnPbTe, SnPbSSe, SnPbSeTe, SnPbSTe;

Si, Ge, SiC, SiGe; or any combination thereof.

According to an embodiment, the first semiconductor material may include

InP, InZnP, InGaP, ZnS, ZnSe, ZnTe, ZnSeS, ZnSeTe, PbSe, PbS, PbTe, AgInZnS, GaN, GaP, GaAs, InGaN, InAs, ZnO, or any combination thereof, and the second semiconductor to the fourth semiconductor material may include

ZnS, ZnSe, ZnTe, ZnSeS, ZnSeTe, ZnO, InP, InS, GaP, GaN, GaO, ZnSeTe, InZnP, InGaP, InGaN, PbS, TiO, SrSe, or any combination thereof.

For example, the first semiconductor material may include ZnSeS, ZnSeTe, or any combination thereof, and

The second semiconductor to the fourth semiconductor material may include ZnS, ZnSe, ZnSeS, ZnSeTe, or any combination thereof.

The quantum dot 10 may have a diameter of, for example, about 1 nm to about 10 nm.

The copolymer ligand 20 may be a ligand derived from the copolymer for quantum dot ligands according to the embodiments. The copolymer ligand 20 may be formed by ligand exchange with a ligand formed in situ during the synthesis of the quantum dot 10.

The copolymer ligand 20 may include a first unit and a second unit, the first unit may include a functional group having a charge transport function, and the second unit may be cross-linked and bonded to a quantum dot.

The functional group having a charge transport function in the first unit may

include a functional group having a hole transport function, an electron transport function, or both (e.g., simultaneously) the hole transport function and the electron transport function. The functional group having the charge transport function may include, for

example, a carbazolyl group, a pyrenyl group, a fluorenyl group, a pyridyl group, an amino group, a pyrimidyl group, a triazine group, a phenanthroline group, a benzimidazole group, an oxadiazole group, a triazole group, an adamantane group, a benzothiadizole group, a diketopyrrolopyrrole group, a truxene group, or a derivative thereof.

The functional group having the charge transport function may include, for example, the functional groups represented by Formulae A-1 to A-15:

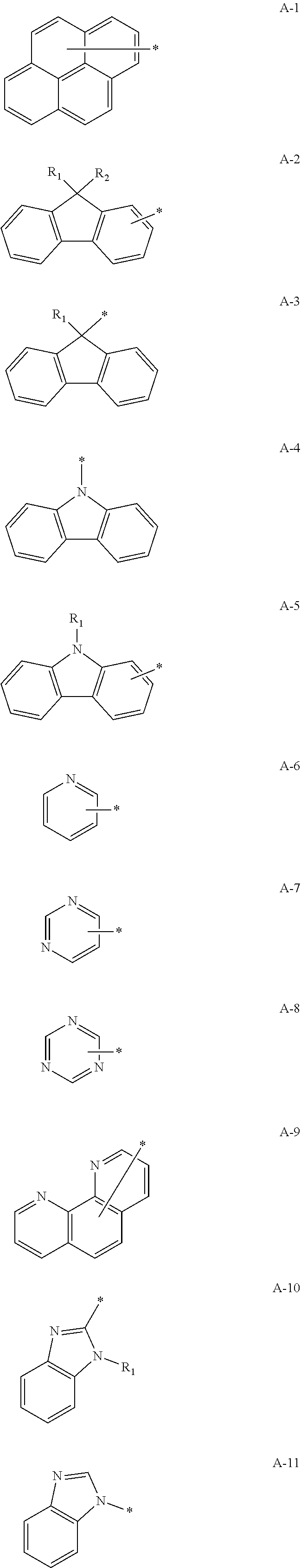

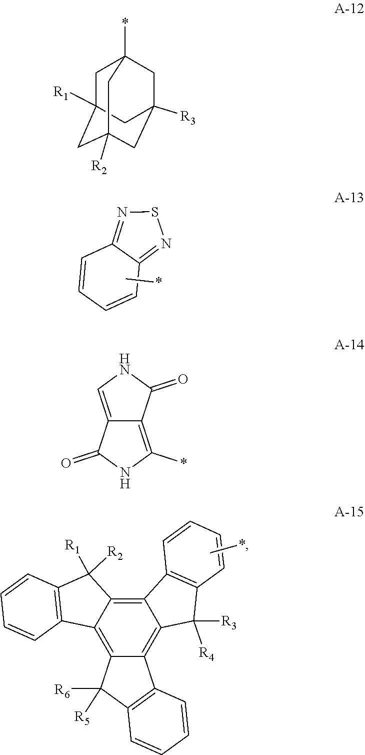

wherein, in Formulae A-1 to A-15,

R₁ to R₆ may each independently be hydrogen, deuterium, —F, —Cl, —Br, —I, a hydroxyl group, a cyano group, a carboxyl group, a C₁-C₂₀ alkyl group, —Si(Q₁)(Q₂)(Q₃), or —N(Q₁)(Q₂),

Q₁ to Q₃ may each independently be hydrogen, a C₁-C₂₀ alkyl group, a phenyl group, a biphenyl group, a terphenyl group, a naphthyl group, or a pyridyl group, and

* is a moiety connected to the quantum dot ligand.

The functional group having a charge transport function may include, in addition to the functional groups represented by Formulae A-1 to A-15,any suitable hole transporting group, any suitable electron transporting group, or any suitable functional group having both (e.g., simultaneously) a hole transport function and an electron transport function. In some embodiments, the functional group represented by

Formulae A-1 to A-15 may further include a substituent. The substituent may include, for example, deuterium, a halogen atom, a hydroxyl group, a cyano group, and/or a C₁-C₂₀ alkyl group.

The crosslinking (e.g., the crosslinking bond) in the second unit may be

formed by hydrogen bonding of a crosslinkable functional group. The crosslinkable functional group may include, for example, an amide group (—CONH-), a urea group (—NHCONH-), or a urethane group (—NHCOO-). The amide group, the urea group, or the urethane group, present at different positions in the quantum dot ligand, may be cross-linked through mutual hydrogen bonding (C═O . . . HN). One or more of the crosslinking (e.g., crosslinking bonds) may be present in the second unit. For example, the second unit may include 1, 2, or 3 crosslinking (e.g., crosslinking bonds).

The bonding to the quantum dot in the second unit may be derived from bonding of a thiol group, an amino group, an amine group, a carboxyl group, a halogen group, an amide group, a sulfonic acid group, or a phosphoric acid group, to the surface of the quantum dot. For example, the bonding to the quantum dot may be derived from a bidentate or tridentate thiol group. For example, the bidentate thiol group may be a 1,2-dithiolane group or a group derived therefrom. The second unit may further include a link portion. For example, when there

are a plurality of crosslinking (e.g., a plurality of crosslinkable functional groups), a link portion may be included between the plurality of crosslinking (e.g., the plurality of crosslinkable functional groups). In some embodiments, a link portion may be included between the crosslinking (e.g., the crosslinkable functional group) and the portion bonding to the quantum dot.

The link portion may include a C₁-C₁₀ alkylene group. The C₁-C₁₀ alkylene

group may include, for example, a methylene group, an ethylene group, an n-propylene group, an n-butylene group, an n-pentylene group, an n-hexylene group, and/or the like, but is not limited thereto. When there are a plurality of link portions, the plurality of link portions may be the same or different from each other.

By adjusting the length of the link portion, the length of the quantum dot ligand may be adjusted. The length of the quantum dot ligand may affect the distance between the quantum dots, thereby affecting the dispersion of the quantum dots.

According to one embodiment, the second unit of the quantum dot ligand may be derived from a unit represented by Formula 1.

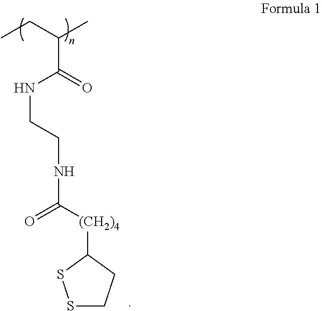

In Formula 1, n may be an integer of 1 to 5.

According to one embodiment, the quantum dot ligand may be derived from a copolymer including a moiety represented by Formula 2.

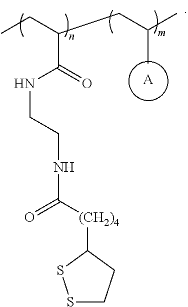

In Formula 2,

n may be an integer from 1 to 5, m may be an integer from 10 to 15,

A may be a suitable charge-transporting functional group. A may be, for example, a functional group represented by any one of Formulae A-1 to A-12 described above.

According to an embodiment, the quantum dot ligand may be a copolymer represented by Formula 3.

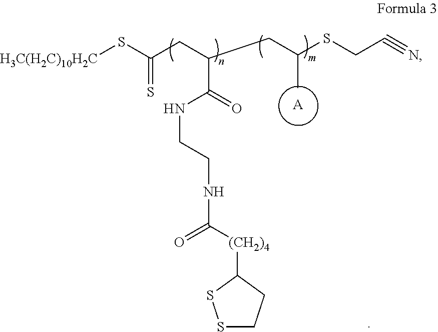

wherein, in Formula 3,

n and A refer to n and A in Formula 2, respectively.

The molar ratio of the first unit to the second unit may be from 1:1 to 15:1, for example, 5:1 to 15:1, or for example, 10:1 to 15:1. When the molar ratio of the first unit to the second unit is within these ranges, the quantum dots having the copolymer ligand may have good or suitable solvent dispersion properties and electron transport properties.

The number average molecular weight (Mn) of the copolymer ligand may be about 1,000 to about 50,000, about 5,000 to about 20,000, or about 5,000 to about For example, the number average molecular weight (Mn) of the copolymer ligand may be about 1,700 to about 12,000. The weight average molecular weight

(Mw) of the copolymer ligand may be about 1,000 to about 50,000, about 5,000 to about 20,000, or about 5,000 to about 10,000. For example, the weight average molecular weight (Mn) of the copolymer ligand may be about 1,700 to about 12,000. The ratio of the number average molecular weight (Mn) to the weight average molecular weight (Mw) of the copolymer ligand may be 1.0 to 1.3. When the molecular weight of the copolymer ligand is within these ranges, the charge transport function of the copolymer ligand is good or suitable, and adhesion of the copolymer ligand to the quantum dots may be suitably maintained (e.g., maintained well).

### Quantum Dot Composition

According to another embodiment, a quantum dot composition including a quantum dot complex according to the embodiments described above and a solvent is provided.

The amount of the quantum dot complex may be 0.1 wt % or more to 60 wt % or less, 0.2 wt % or more to 30 wt % or less, or 0.5 wt % or more to 20 wt % or less, based on the total weight of the quantum dot composition, but is not limited thereto. Within these ranges, the quantum dot composition is suitable for usage in manufacturing a functional layer such as an emission layer and/or a charge transport layer of a light-emitting device in a solution process.

The quantum dot composition allows the quantum dot complex in the composition to be uniformly dispersed without being separated from each other to form a film having improved uniformity. In some embodiments, by utilizing the quantum dot composition, the charge injection balance of the light-emitting device may be improved, and luminous efficiency and/or lifetime may be improved.

Any suitable solvent capable of dispersing the quantum dot complex may be selected as the solvent.

For example, the solvent may include: alkyleneglycol alkylethers such as ethyleneglycol monomethylether, ethyleneglycol monoethylether, ethyleneglycol monopropylether, ethyleneglycol monobutylether, propyleneglycol monomethylether, and/or propyleneglycol methylethylether; diethyleneglycol dialkylethers such as diethyleneglycol dimethylether, diethyleneglycol diethylether, diethyleneglycol dipropylether, and/or diethyleneglycol dibutylether; alkyleneglycol alkyletheracetates such as methylcellosolveacetate, ethylcellosolveacetate, propyleneglycol monomethyletheracetate, propyleneglycol monoethyletheracetate, and/or propyleneglycol monopropylether acetate; alkoxyalkylacetates such as methoxybutyl acetate and methoxypentyl acetate; aromatic hydrocarbons such as benzene, toluene, xylene, and/or mesitylene; ketones such as methyl ethyl ketone, acetone, methyl amyl ketone, methyl isobutyl ketone, and/or cyclohexanone; alcohols such as ethanol, propanol, butanol, hexanol, cyclohexanol, ethylene glycol, and/or glycerin; esters such as 3-ethoxypropionic acid ethyl ester, 3-methoxypropionic acid methyl ester, and/or 3-phenyl-propionic acid ethyl ester; cyclic esters, such as γ-butyrolactone; methoxybenzene(anisole); or any combination thereof.

The amount of the solvent may be 40 wt % or more to 99.9 wt % or less, for example, 70 wt % or more to 99.8 wt % or less, for example, 80 wt % or more to 99.5 wt % or less, based on the total weight of the quantum dot composition. However, the disclosure is not limited thereto. Within these ranges, the quantum dot complex may be properly dispersed in the quantum dot composition, and a quantum dot concentration suitable for a soluble process may be obtained.

According to one embodiment, the quantum dot composition may further include a monomer, a polymer resin, a curing agent, a dispersant, a scattering agent, or one or more suitable other additives as long as the additives do not affect the physical properties of the quantum dot complex.

The quantum dot composition may be utilized to form a film by any suitable method, such as spin coating, inkjet printing, and/or the like.

### Light-Emitting Device

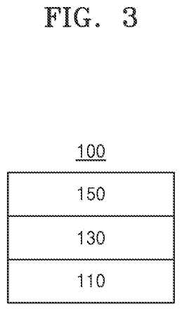

FIG. 3 is a schematic cross-sectional view showing a structure of a light-emitting device 100 according to an embodiment. The light-emitting device 100 includes a first electrode 110, a functional layer 130, and a second electrode 150. A substrate may be additionally disposed on a lower portion of the first electrode 110 or an upper portion of the second electrode 150 illustrated in FIG. 3.

The first electrode 110 may be an anode or a cathode, and may be a transmissive, transflective, or reflective electrode. The second electrode 150 may be a cathode or an anode depending on the first electrode, and may be a transmissive, transflective, or reflective electrode.

The functional layer 130 may be disposed on the first electrode 110. The functional layer 130 includes an emission layer.

The emission layer may include the quantum dot according to the embodiments described above. The emission layer may be formed from the quantum dot composition according to the embodiments described above.

In an embodiment, the emission layer may include a host and a dopant. The dopant may include a phosphorescent dopant, a fluorescent dopant, or any combination thereof. In some embodiments, the emission layer may include a delayed fluorescence material. The delayed fluorescence material may act as a host or a dopant in the emission layer. The host may include (e.g., consist of) a single host or a mixed host.

The functional layer 130 may further include a hole transport region and an electron transport region. The hole transport region or the electron transport region may include a single layer or multiple layers. The hole transport region may include a hole injection layer, a hole transport layer, an emission auxiliary layer, an electron blocking layer, or any combination thereof. The electron transport region may include a buffer layer, a hole blocking layer, an electron control layer, an electron transport layer, an electron injection layer, or any combination thereof. The layers may include a single material or a plurality of different materials.

The quantum dot according to the embodiments may be included in the hole transport region or the electron transport region. A layer including the quantum dot may be formed from the quantum dot composition according to the embodiments described above.

In some embodiments, the functional layer 130 may include i) two or more emitting units sequentially stacked between the first electrode 110 and the second electrode 150, and ii) a charge generation layer disposed between the two or more emitting units. Each emitting unit includes an emission layer, and may further include a hole transport region and an electron transport region. The quantum dot according to the embodiments described above may be included in the emission layer, the hole transport region, and/or the electron transport region, in the emitting unit. The quantum dot included in the emission layer, the hole transport region, and/or the electron transport region in the emitting unit may be formed from the quantum dot composition according to embodiments described above.

### Electronic Apparatus

The quantum dot complex according to embodiments described above may be utilized in one or more suitable electronic devices or optical members. For example, the quantum dot complex may be utilized in an electronic device such as a display, a solar cell, lighting, bioimaging, and/or a biosensor, and/or an optical member such as a color conversion member.

Hereinafter, copolymers for quantum dot ligands, quantum dot complexes, and light-emitting devices, according to embodiments, will be described in more detail, with reference to Synthesis Examples and Examples. The expression “B was utilized instead of A” used in describing Synthesis Examples refers to that an identical molar equivalent of B was utilized in place of A.

### EXAMPLES

### Example 1-1

### Preparation of ZnSeTe/ZnSe/ZnS Quantum Dot Complex (QD/LS15) with PVK-b-BTM Ligand

### Synthesis of PVK-b-BTM Block Copolymer Ligands

### Synthesis of BTM Molecules

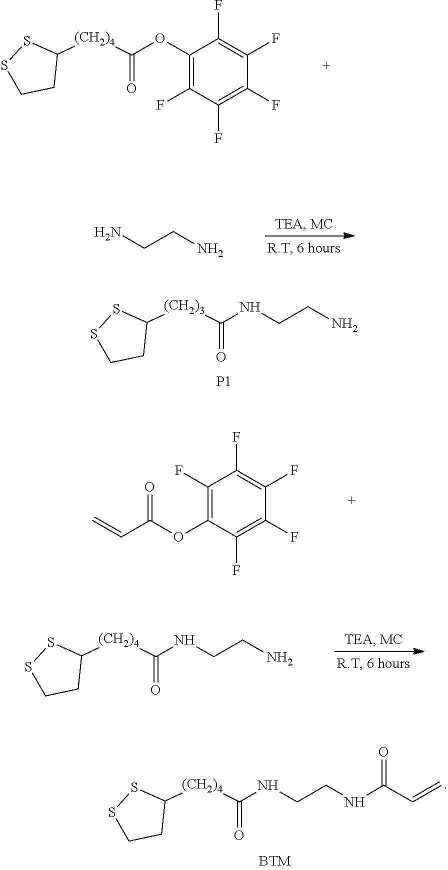

In a 100 mL 1-neck round-bottom flask under nitrogen atmosphere, α-(-(±)-lipoic acid (1.78 g, 8.5 mmol) was dissolved in 30 mL of anhydrous methylene chloride (MC). 3 mL of triethylamine (TEA) was injected into this solution, and stirred at room temperature for 1 hour, and then, pentafluorophenyl trifluoroacetate (0.476 g, 17 mmol) was injected thereto, followed by stirring at room temperature for 3 hours. To terminate the reaction, an extraction process was performed thereon three times utilizing deionized water at 0° C. to obtain an organic layer. Then, utilizing methylene chloride (MC) as an eluent, the organic layer was purified through flash column chromatography, and the yellow viscous liquid perfluorophenyl 5-(1,2-dithiolan-3-yl)pentanoate was obtained.

Pentafluorophenyl lipoic acid (PFLA) (1.95 g, 5.0 mmol) was dissolved in 36 mL of anhydrous MC in a 100 mL 1-neck round bottom flask under a nitrogen environment. 3.0 mL of TEA was injected into this solution and stirred at room temperature for 30 minutes, and then 1,2-ethylene diamine (0.6 g, 10 mmol) was rapidly added thereto and stirred for 6 hours. To terminate the reaction, the solution was filtered under reduced pressure to remove a solid product therefrom, and an extraction process was performed thereon three times with an aqueous NaCl solution at 0° C. to obtain compound P1 as a yellow viscous liquid (precursor).

Pentafluorophenyl acrylate (PFA) (0.952 g, 4 mmol) was dissolved in anhydrous MC (30 mL) in a 100 mL 1-neck round-bottom flask under a nitrogen environment. 3.0 mL of TEA was injected into this solution and stirred at room temperature for 30 minutes, and then, compound P1 (1.987 g, 8 mmol) was rapidly added thereto and stirred for 18 hours. To terminate the reaction, an extraction was performed three times with an aqueous NaCl solution at 0° C., and the organic layer was purified through flash column chromatography utilizing EtOH:MC (1:19, v:v) as a developing solution to obtain N-(2-aminoethyl)-5-(1,2-dithiolan-3-yl)pentanamide (BTM).

### 2) Synthesis of PVK-b-BTM Copolymer Ligand

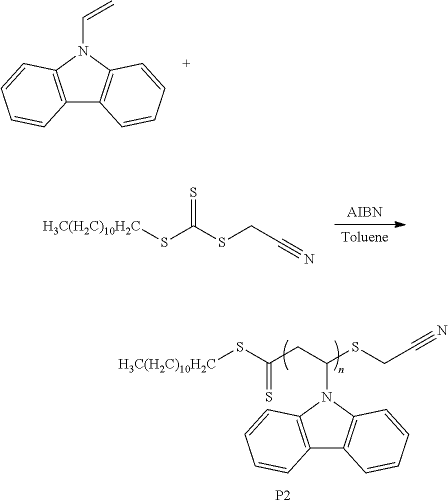

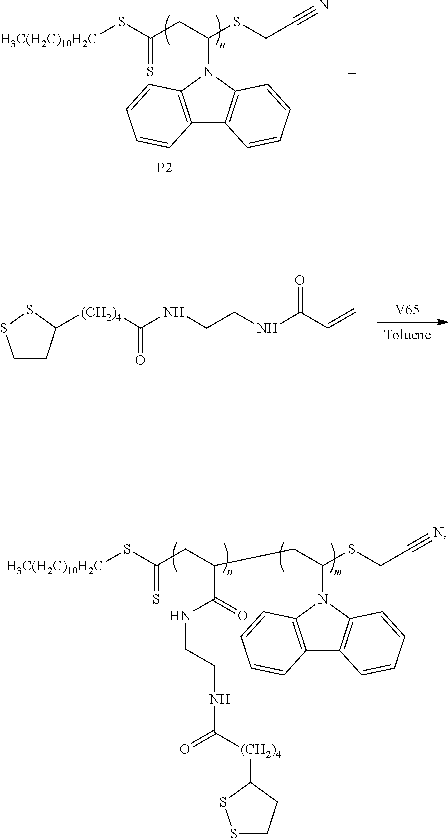

N-vinylcarbazole (3.4 g, 2.07 mmol), cyanomethyl dodecyl trithiocarbonate (6.8 mg, 20.7 μmmol), and N,N′-azobisisobutyronitrile (AIBN) (3.4 mg 40.7 μmmol) were placed in a 1-neck round-bottom flask and dissolved in 20 mL of anhydrous toluene. Freeze-pump-thaw was performed three times utilizing liquid nitrogen, and the reactor was inactivated through a nitrogen purge for 30 minutes. Thereafter, the substances in the flask were polymerized through reflux stirring at 80° C. under a nitrogen environment for 24 hours. The reaction was terminated utilizing an ice bath, and thereafter, a purification process was performed three times utilizing EtOH to obtain compound P2.

Compound P2 (0.5 g, 2.59 mmol), BTM (0.453 g, 1.5 mmol), and 2,2′-Azobis(2,4-dimethylvaleronitrile (V65) (3.7 mg, 15 μmol) were added to a 1-neck round-bottom flask, and dissolved in 20 mL of anhydrous toluene. Freeze-pump-thaw was performed three times utilizing liquid nitrogen, and the inside of the reactor was inactivated through a nitrogen purge for 30 minutes. Thereafter, the substances in the flask were polymerized through reflux stirring at 60° C. under a nitrogen environment for 24 hours. The reaction was terminated utilizing an ice bath, and thereafter, a purification process was performed by precipitation with EtOH three times to obtain a PVK-b-BTM copolymer (e.g., copolymer ligand) having a molar ratio of PVK unit to BTM unit (m:n) of 15:1.

### (2) Synthesis of ZnSTe/ZnSe/ZnS Quantum Dot

### 1) Precursor Synthesis

Se (0.3158 g, 40 mmol) and diphenylphosphine (DPP) (2 mL) were placed in a 20 mL vial and stirred at 220° C. to prepare Se precursor 1 (Se and DPP stock solution).

Se (0.4 g, 5 mmol) and trioctyl phosphine (TOP) (4 mL) were placed in a 20 mL vial and stirred at 220° C. to prepare Se precursor 2 (Se and TOP stock solution).

Te (0.035 g, 0.274 mmol) and trioctyl phosphine (5 mL) were placed in a 20 mL vial and stirred at 220° C. to prepare a Te precursor (Te and TOP stock solution).

Zinc acetate (1.1 g, 6 mmol), oleic acid (3.8 mL), and 1-octadecene (2.8 mL) were placed in a 20 mL vial and stirred at 150° C. to prepare Zn precursor 1 (zinc oleate solution).

Zinc acetate (0.917 g, 5 mmol), oleic acid (3.2 mL), and trioctylamine (7.0 mL) were placed in a 20 mL vial and stirred at 250° C. to prepare Zn precursor 2 (zinc oleate solution).

2 mmol of S (trace metal sulfur) was dissolved in trioctylphosphine (TOP) at 200° C. in an N₂ flow and then the reaction temperature was lowered to room temperature to prepare S precursor 2 (S-TOP).

### 2) ZnSeTe Core Synthesis

Zinc acetate (0.367 g, 0.2 mmol), oleic acid (2 mL), and 1-octadecene (15 mL) were placed in a 3-neck round-bottom flask, and stirred at 150° C. under vacuum for 30 minutes. Then, 0.5 mL of the Se precursor 1 and 0.8 mL of the Te precursor were sequentially injected at 220° C. to synthesize a ZnSeTe core.

### 3) Synthesis of ZnSe Shell on ZnSeTe Core

Then, the temperature of the reactant was raised from 220° C. to 340° C., 4 mL of the zinc precursor 1 (zinc oleate solution) and 0.6 mL of the Se precursor 2 were added thereto, and stirred at 340° C. for 30 minutes to synthesize a ZnSe shell.

### 4) ZnS Shell Synthesis on ZnSe Shell

Then, when the temperature of the reactant was 340° C., 3 mL of zinc precursor 1 (zinc oleate) and 1.6 mL of S precursor 2 (S-TOP) were added, and stirred at 340° C. for 30 minutes to form ZnS on the ZnSe shell to obtain ZnSeTe/ZnSe/ZnS quantum dot.

### (3) PVK-b-BTM Ligand Formation

ZnSeTe/ZnSe/ZnS quantum dot and PVK-b-BTM block copolymer synthesized as described above were dissolved in anhydrous toluene in a weight ratio of 1:10. The resultant was sonicated at 0° C. for 10 minutes under a nitrogen atmosphere and stirred at room temperature for 1 hour to obtain the quantum dot functionalized with a PVK-b-BTM block copolymer. This quantum dot was purified by repeating centrifugation 3 times for 15 minutes at 8,000 rpm at 0° C. utilizing n-hexane, and the exchange of the ligand of the ZnSeTe/ZnSe/ZnS quantum dot with the PVK-b-BTM block copolymer was confirmed by infrared (IR) spectroscopy, UV/VIS spectroscopy, and photoluminescence (PL).

### Example 1-2

### Preparation of ZnSeTe/ZnSe/ZnS Quantum Dot Complex (QD/LS10) with PVK-b-BTM Ligand

A quantum dot complex was synthesized in substantially the same manner as in Example 1-1, except that the molar ratio of PVK unit to BTM unit was 10:1 during PVK-b-BTM ligand synthesis.

### Comparative Example 1-1

### Preparation of a ZnSeTe/ZnSe/ZnS Quantum Dot Complex (QD) having an Oleic Acid Ligand

A quantum dot complex was synthesized in substantially the same manner as in Example 1-1, except that the exchange with the PVK-b-BTM copolymer ligand was not performed. By not undergoing ligand exchange, the oleic acid ligand generated during ZnSeTe/ZnSe/ZnS quantum dot synthesis is maintained as it is.

### Comparative Example 1-2

### Preparation of ZnSeTe/ZnSe/ZnS Quantum Dot Complex Having Poly BTM Ligand

For the ZnSeTe/ZnSe/ZnS quantum dot synthesized in substantially the same manner as in Example 1-1, a quantum dot complex in which poly BTM was introduced as a ligand was formed through a ligand exchange reaction into a poly BTM copolymer ligand.

### Comparative Example 1-3

### Preparation of ZnSeTe/ZnSe/ZnS Quantum Dot Complex with PVK-b-POVDAC Ligand

For the ZnSeTe/ZnSe/ZnS quantum dot synthesized in substantially the same manner as in Example 1-1, a quantum dot complex in which PVK-b-poly(octadecyl-pvinylbenzyl-dimethylammonium chloride) (PVK-b-POVDAC) was introduced as a ligand was formed through a ligand exchange reaction into a PVK-b-POVDAC copolymer ligand.

### Identification of PVK-b-BTM Copolymer Ligands

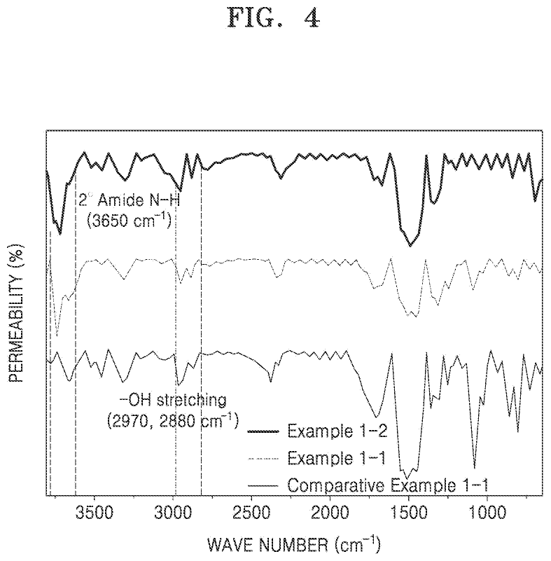

It was confirmed by FT-IR whether the oleic acid ligand was exchanged with the PVK-b-BTM copolymer ligand during the synthesis of the ZnSeTe/ZnSe/ZnS quantum dot complexes of Examples 1-1 and 1-2. FIG. 4 is a Fourier-transform infrared spectroscopy (FT-IR) spectrum of the quantum dot complex of Examples 1-1 and 1-2 and Comparative Example 1-1.

Referring to the graph of FIG. 4, in the FT-IR of the quantum dot complexes of Examples 1-1 and 1-2, the peak of the secondary amine included in the BTM unit is observed at about 3,650 cm⁻¹, and in the case of the quantum dot complex of Comparative Example 1-1, which was not subjected to the ligand exchange, the peak of the secondary amine is not observed. In addition, peaks due to —OH stretching of about 2,970 cm⁻¹ and about 2,880 cm⁻¹ observed in FT-IR of the quantum dot complex of Comparative Example 1-1, are reduced in the case of the quantum dot complexes of Examples 1-1 and 1-2. This result shows that the oleic acid ligand was exchanged with the PVK-b-BTM copolymer ligand in the quantum dot complexes of Examples 1-1 and 1-2.

### Evaluation Example 1

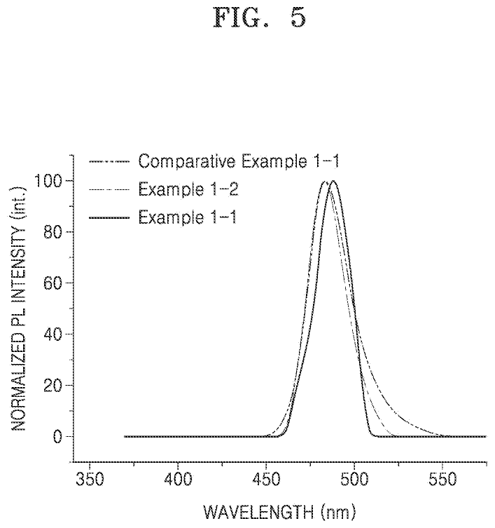

FIG. 5 is a photoluminescence spectrum of the quantum dot complex of Examples 1-1 and 1-2 and Comparative Example 1-1. The quantum dot complexes of Examples 1-1 and 1-2 were dissolved in toluene, and the quantum dot complex of Comparative Example 1 was dissolved in n-hexane to measure photoluminescence at room temperature utilizing a spectrometer (FLS920, Edinburgh Instruments).

Referring to FIG. 5, the quantum dots of Examples 1-1 and 1-2 and Comparative Example 1-1 have an emission peak near 480 nm, and the width of the emission peak of the emission peak is decreased in this order of Comparative Example 1-1, Example 1-2, and Example 1-1 so that the width of the emission peak of the quantum dot of Example 1-1 is the narrowest. It is thought that in the case of quantum dot complexes of Examples 1-1 and 1-2, the surface defects of the quantum dots are reduced by the PVK-b-BTM copolymer ligand. Accordingly, the width of the emission peak thereof is reduced compared to the quantum dot complex of Comparative Example 1-1. On the other hand, it is thought that the narrower width of the emission peak of the quantum dot complex of Example 1-1 than that of Example 1-2 is due to the improvement of charge transport properties resulting from the increased ratio of PVK units.

### Evaluation Example 2

The quantum dot complexes of Examples 1-1 and 1-2 and Comparative Example 1-1 were applied to the emission layer of the light-emitting device, and current efficiency and luminance thereof were measured.

### Example 2-1

### Preparation of Quantum Dot Composition

The quantum dot complex prepared in Example 1-1 was dispersed in a

solvent (anhydrous toluene) in an amount of 90 wt % based on the total weight of 100 wt % of the composition to prepare a quantum dot composition.

### Example 2-2

### Preparation of Quantum Dot Composition

A quantum dot composition was prepared in substantially the same manner as in Example 2-1, except that the quantum dot complex of Example 2-1 was utilized instead of the quantum dot complex of Example 1-1.

### Comparative Example 2-1

### Preparation of Quantum Dot Composition

A quantum dot composition was prepared in substantially the same manner as in Example 2-1, except that the quantum dot complex of Comparative Example 1-1 was utilized instead of the quantum dot complex of Example 1-1.

### Example 3-1

### Fabrication of a Quantum Dot Light-Emitting Device

A 15 Ω/cm² (1200 Å) ITO glass substrate (made by Corning) was cut into a size of 50 mm×50 mm×0.7 mm and sonicated utilizing isopropyl alcohol and pure water each for 5 minutes, and then exposed to ultraviolet (UV) light for 30 minutes and then ozone to clean.

On the resultant glass substrate, which had been cleaned, PEDOT:PSS was spin-coated, and baked at 150° C. for 30 minutes to form a 35 nm-thick hole injection layer. Poly(9,9-dioctylfluorene-co-N-(4-butylphenyl)diphenyl-amine (TFB) was spin-coated on the hole injection layer and baked at 150° C. for 30 minutes to form a 30 nm-thick hole transport layer. The quantum dot composition of Example 2-1 was spin-coated on the hole transport layer and baked at 140° C. for 10 minutes to form an emission layer having a thickness of 28 nm. Then, an ethanol solution in which ZnMgO nanoparticles were dispersed at 2.0 wt %, was spin-coated on the emission layer and baked at a temperature of 100° C. for 10 minutes in a glove box under a nitrogen atmosphere to form an electron transport layer having a thickness of 30 nm. Aluminum (Al) was deposited to a thickness of 100 nm on the electron transport layer to form an anode, thereby completing the manufacture of a quantum dot light-emitting device.

### Example 3-2

### Preparation of Quantum Dot Light-Emitting Device

A quantum dot light-emitting device was manufactured in substantially the same manner as in Example 3-1, except that the quantum dot composition of Example 2-2 was utilized instead of the quantum dot composition of Example 2-1 when the emission layer was formed.

Comparative Example 1-1: Preparation of quantum dot light-emitting device

A quantum dot light-emitting device was manufactured in substantially the same manner as in Example 3-1, except that the quantum dot composition of Comparative Example 2-1 was utilized instead of the quantum dot composition of Example 2-1 when the emission layer was formed.

The current-efficiency and luminance of the organic light-emitting devices of Examples 3-1 and 3-2 and Comparative Example 3-1 were measured utilizing a current-voltmeter (BS1-NA201, Hanyoung Nux) and a luminance meter (SM-208, Chosun Instrument).

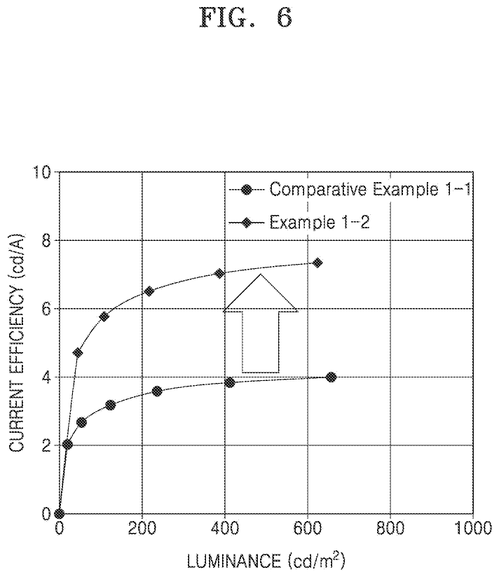

FIG. 6 is a graph of current efficiency versus luminance of the quantum dot light-emitting device of Example 3-2 and Comparative Example 3-1. Referring to FIG. 6, it can be seen that the current efficiency of the light-emitting device of Example 3-2 including the quantum dot complex having a PVK-b-BTM block copolymer ligand was nearly twice as high as that of the quantum dot light-emitting device of Comparative Example 3-1 including the quantum dot complex having an oleic acid ligand.

It is thought that the high current efficiency of the quantum dot light-emitting device of Example 3-2 is due to the reduction of surface defects of the quantum dots and the improvement of charge transporting properties by the PVK-b-BTM block copolymer ligand.

Embodiments of the disclosure can provide quantum dots having good or suitable charge mobility while ensuring dispersion in organic solvents without aggregation, by introducing a copolymer ligand including a unit having a charge transport function and a crosslinkable unit, and can thereby provide a reliable device.

The use of “may” when describing embodiments of the present disclosure refers to “one or more embodiments of the present disclosure”. As used herein, the term “and/or” includes any and all combinations of one or more of the associated listed items. Throughout the disclosure, the expression, such as “at least one of a, b or c”, “at least one selected from a, b, and c”, “at least one selected from the group consisting of a, b, and c”, “at least one from among a, b, and c”, etc., indicates only a, only b, only c, both (e.g., simultaneously) a and b, both (e.g., simultaneously) a and c, both (e.g., simultaneously) b and c, all of a, b, and c, or variation(s) thereof.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A copolymer for a quantum dot ligand, the copolymer comprising:
a first unit comprising a functional group, the functional group having a charge transport function; and
a second unit comprising at least one crosslinkable functional group and at least one functional group capable of bonding to a quantum dot.

2. The copolymer of claim 1, wherein the functional group, having the charge transport function, comprises a carbazolyl group, a pyrenyl group, a fluorenyl group, a pyridyl group, a pyrimidyl group, a triazine group, a phenanthroline group, a benzimidazole group, an oxadiazole group, a triazole group, an adamantane group, a benzothiadizole group, a truxene group, a diketopyrrolopyrrole group, or any combination thereof.

3. The copolymer of claim 1, wherein the functional group, having the charge transport function, comprises at least one of functional groups represented by Formula A-1 to Formula A-15: 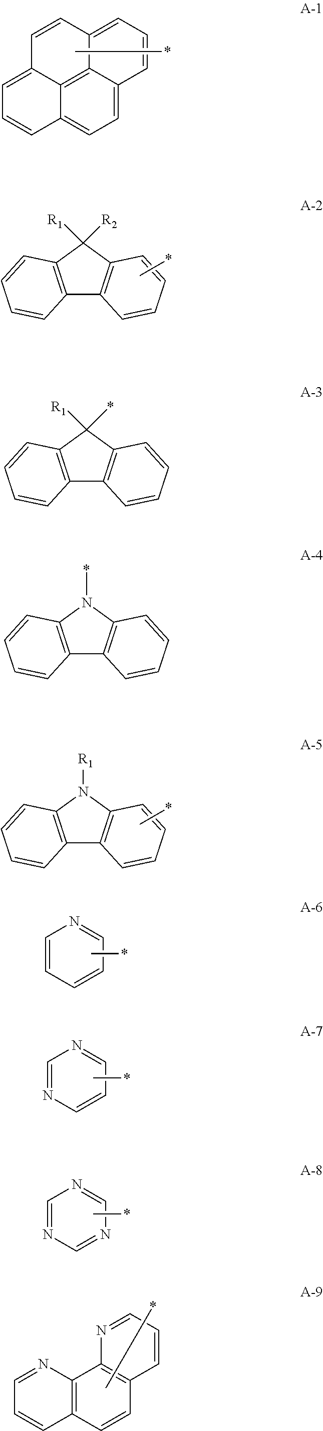 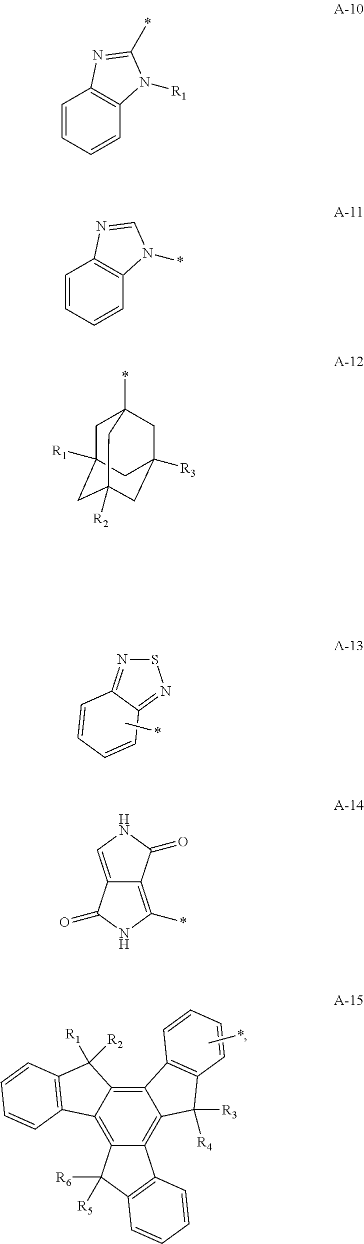
wherein, in Formulae A-1 to A-15,
R₁ to R₆ are each independently hydrogen, deuterium, —F, —Cl, —Br, —I, a hydroxyl group, a cyano group, a carboxyl group, a C₁-C₂₀ alkyl group, —Si(Q₁)(Q₂)(Q₃), or —N(Q₁)(Q₂),
Q₁ to Q₃ are each independently hydrogen, a C₁-C₂₀ alkyl group, a phenyl group, a biphenyl group, a terphenyl group, a naphthyl group, or a pyridyl group, and
* is a site connected to the copolymer.

4. The copolymer of claim 1, wherein
the crosslinkable functional group comprises an amide group (—CONH-), a urea group (—NHCONH-), or a urethane group (—NHCOO-).

5. The copolymer of claim 1, wherein
the functional group, capable of bonding to the quantum dot, comprises a thiol group, an amino group, an amine group, a carboxyl group, a halogen group, an amide group, a sulfonic acid group, or a phosphoric acid group.

6. The copolymer of claim 1, wherein
the functional group, capable of bonding to the quantum dot, is a bidentate group or a tridentate group.

7. The copolymer of claim 1, wherein:
the second unit further comprises a first link portion positioned between the crosslinkable functional group and the functional group capable of binding to the quantum dot; and
when the crosslinkable functional group comprises two or more crosslinkable functional groups, a second link portion is positioned between the two or more crosslinkable functional groups.

8. The copolymer of claim 1, wherein the copolymer comprises a moiety represented by Formula 2: 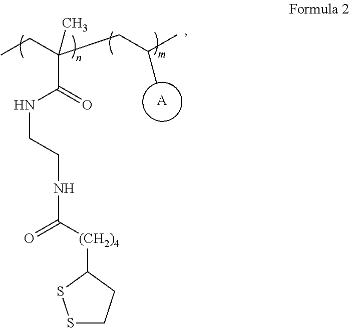
wherein, in Formula 2,
n is an integer selected from 1 to 5, and m is an integer selected from 10 to 15, A comprises a functional group represented by one of Formulae A-1 to A-15: 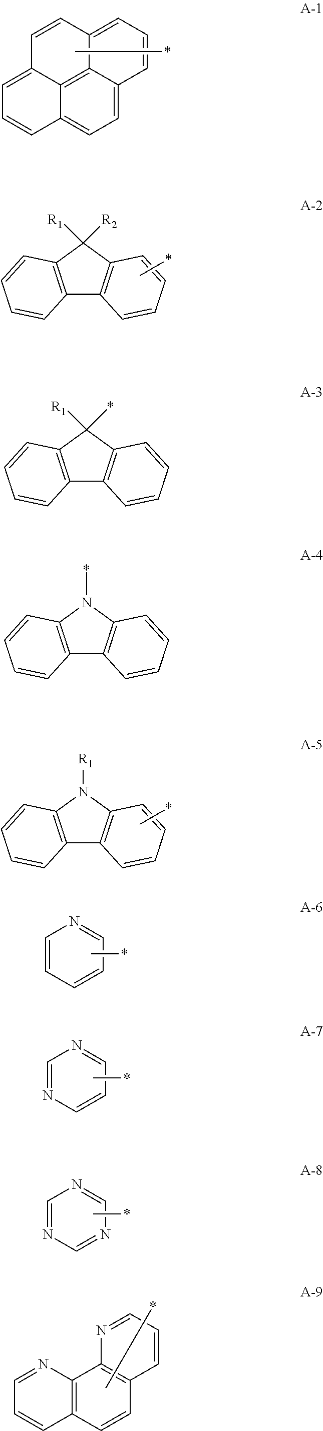 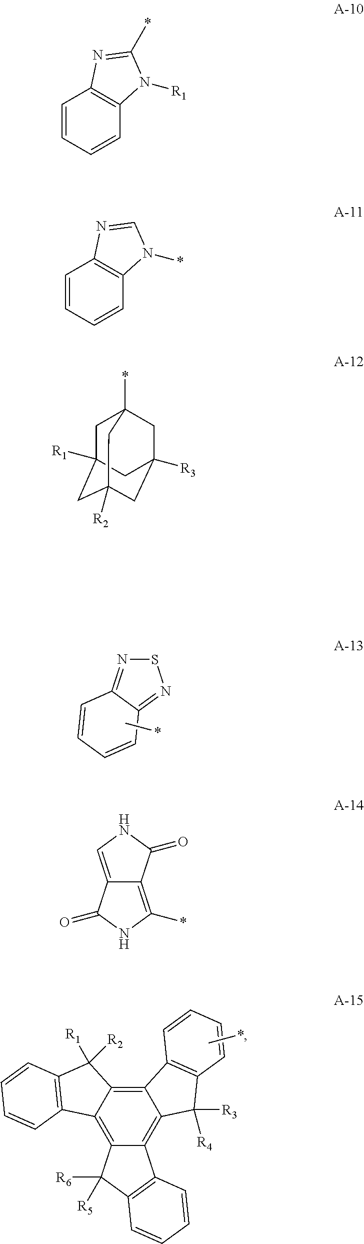
wherein, in Formulae A-1 to A-15,
R₁ to R₆ are each independently hydrogen, deuterium, —F, —Cl, —Br, —I, a hydroxyl group, a cyano group, a carboxyl group, a C₁-C₂₀ alkyl group, —Si(Q₁)(Q₂)(Q₃), or —N(Q₁)(Q₂),
Q₁ to Q₃ are each independently hydrogen, a C₁-C₂₀ alkyl group, a phenyl group, a biphenyl group, a terphenyl group, a naphthyl group, or a pyridyl group, and
* is a site bonded to the moiety.

9. The copolymer of claim 1, wherein a molar ratio of the first unit to the second unit is 5:1 to 20:1.

10. The copolymer of claim 1, wherein a number average molecular weight (Mn) of the copolymer is about 2,000 to about 50,000.

11. A quantum dot complex comprising:
a quantum dot, and
a quantum dot ligand bonded to the quantum dot,
wherein the quantum dot ligand comprises:
a first unit comprising a functional group having a charge transport function; and
a second unit comprising a cross-linked portion and a quantum dot-bonded portion bonded to the quantum dot.

12. The quantum dot complex of claim 11, wherein
the functional group, having the charge transport function, comprises a carbazolyl group, a pyrenyl group, a fluorenyl group, a pyridyl group, a pyrimidyl group, a triazine group, a phenanthroline group, a benzimidazole group, an oxadiazole group, a triazole group, or any combination thereof.

13. The quantum dot complex of claim 11, wherein
the cross-linked portion is derived from hydrogen bonding of an amide group (—CONH-), a urea group (—NHCONH-), or a urethane group (—NHCOO-).

14. The quantum dot complex of claim 11, wherein
the quantum dot-bonded portion bonded to the quantum dot is derived from bonding of a thiol group, an amino group, an amine group, a carboxyl group, a halogen group, an amide group, a sulfonic acid group, or a phosphoric acid group, to a surface of the quantum dot.

15. The quantum dot complex of claim 11, wherein:
the second unit comprises a first link portion positioned between the cross-linked portion and the quantum dot-bonded portion; and
when the cross-linked portion comprises two or more cross-linked portions, a second link portion is positioned between the two or more cross-linked portions.

16. The quantum dot complex of claim 11, wherein
the quantum dot has a core-shell structure comprising:
a core comprising a first semiconductor; and
a shell around the core and comprising a second semiconductor.

17. The quantum dot complex of claim 16, wherein
the first semiconductor and the second semiconductor each independently comprise:
ZnS, ZnSe, ZnTe, ZnO, MgSe, MgS, ZnSeS, ZnSeTe, ZnSTe, MgZnSe, MgZnS, or CdZnSeS;
GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaN, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, InGaZnP, or InAlZnP;
TiO, GaO, GaS, GaSe, Ga₂Se₃, GaTe, InS, InSe, In₂S₃, In₂Se₃, or InTe;
InGaS₃, or InGaSe₃;
AgInS, AgInS₂, CuInS, CuInS₂, CuGaO₂, AgGaO₂, AgAlO₂, or AgInZnS;
SrSe, SnS, SnSe, SnTe, PbS, PbSe, PbTe; SnSeS, SnSeTe, SnSTe, PbSeS, PbSeTe, PbSTe, SnPbS, SnPbSe, SnPbTe, SnPbSSe, SnPbSeTe, or SnPbSTe;
Si, Ge, SiC, or SiGe; or
any combination thereof.

18. The quantum dot complex of claim 11, wherein the first semiconductor comprises InP, InZnP, InGaP, CdSe, CdS, CdTe, ZnS, ZnSe, ZnTe, CdSeTe, CdZnS, CdSeS, PbSe, PbS, PbTe, AgInZnS, HgS, HgSe, HgTe, GaN, GaP, GaAs, InGaN, GaAs , InAs, ZnO, or any combination thereof, and the second semiconductor comprises ZnS, ZnSe, ZnTe, ZnO, CdS, CdSe, CdTe, CdO, InP, InS, GaP, GaN, GaO, InZnP, InGaP, InGaN, InZnSCdSe, PbS, TiO, SrSe, HgSe, or any combination thereof.

19. A quantum dot composition comprising:
the quantum dot complex of claim 11; and
a solvent.

20. A light-emitting device comprising:
a first electrode;
a second electrode facing the first electrode; and
a functional layer between the first electrode and the second electrode, wherein the functional layer comprises the quantum dot complex of claim 11.
